(19) United States
(12) Patent Application Publication
(10) Pub. No.: US 2006/0180835 A1
(43) Pub. Date: Aug. 17, 2006

(54) Semiconductor component with integrated backup capacitance

(76) Inventor: Gerald Sellmair, Landshut (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/321,351

(22) Filed: Dec. 29, 2005

(30) Foreign Application Priority Data
Dec. 29, 2004 (DE) 10 2004 063 277.4

(51) Int. Cl. H01L 29/76

(52) U.S. Cl. 257/288

(57) ABSTRACT

On embodiment of the invention provides a semiconductor component with at least one thin oxide transistor, the gate of which is directly connected to a first electrical potential by means of a connecting element. The connecting element contains a thermal desired breaking point. In order to realize an integrated backup capacitance, at least one of the further terminals of the thin oxide transistor (source or drain) is directly connected to a second potential, that is different from the first potential.

### CROSS-REFERENCE TO RELATED APPLICATIONS

This Utility Patent Application claims priority to German Patent Application No. DE 10 2004 063277.4, filed on Dec. 29, 2004, which is incorporated herein by reference.

### BACKGROUND

The present invention relates to a semiconductor component with integrated backup capacitance.

On account of decreasing supply voltages, it is of increasing importance in semiconductor circuit technology to preclude or at least minimize fluctuations of said supply voltage. Particularly in the case of so-called “logic products”, such as, for example, baseband controllers for mobile radio applications or transceivers for wire-based data communication, there is a concrete need for a stable internal voltage supply in order to avoid data losses.

In order to reduce the influence of effects, such as, for example, a quasi-local drop in the supply voltage (IR drop) or periodic fluctuations of the supply voltage (ground bounce), caused by the effect of parasitic inductances and nonreactive resistances during switching operations, local capacitances are distributed areally over the chip. These capacitances are called backup capacitances. In this case, by way of example, gate capacitances that are realized in the field effect transistors can be utilized by filler cells distributed in the chip, for example, for improved wiring capability.

While in many operating states said gate capacitances have a performance-limiting effect, that is to say adversely affect, for example, the maximum clock frequency of the semiconductor component, said capacitances are utilized positively here. In practice, however, there is the disadvantage that in the case of permanent breakdown of said capacitances, which may be brought about, for example, by the action of electrostatic discharges (ESD), the entire semiconductor component is destroyed.

In order to eliminate this risk, existing rules for chip design (design rules) demand, for example, either that transistor gates are in principle not permitted to be directly connected to a supply voltage or that breakdown-resistant thick oxide transistors are used. However, thick oxide transistors have only a low capacitance value per unit area in comparison with the thin oxide transistors usually used in the chip—which thin oxide transistors are often also called “core” transistors both on account of their use and for differentiation from thick oxide transistors used in the input/output region. Moreover, thick oxide transistors require greater distances from adjacent circuit sections on account of their dimensioning and different processing during fabrication.

A further solution is to use pn junction capacitances of, for example, filler cells as backup capacitances. In this case, however, there is the disadvantage that said pn junction capacitances have a relatively low capacitance value per unit chip area.

Therefore, there is a comparatively low capacitance value per unit area consistently when using both pn junction capacitances and also gate capacitances of thick oxide transistors.

### SUMMARY

One embodiment of the present invention creates a semiconductor component with integrated backup capacitance that has a maximum capacitance in conjunction with a minimum chip area. In the semiconductor component, a short circuit of the backup capacitance does not cause failure of the entire semiconductor component.

In one embodiment of the semiconductor component, the gate capacitance of a field effect transistor in CMOS technology (MOSFET) is utilized as backup capacitance. In this case, the gate of a thin oxide transistor is connected to a first supply voltage via a connecting element. At least one of the further terminals of the transistor, that is to say source or drain, is connected to a second supply voltage. In this case, it is possible, either for complementary, symmetrical supply voltages to be used or for one of the two supply voltages to be realized as zero potential (ground potential).

In one embodiment, a MOS capacitor is realized by this interconnection. In order then during peak loading, which may be caused, for example, by ESD pulses (electrostatic discharge), to prevent a permanent short circuit—which destroys the semiconductor component—from arising on account of breakdown of the gate oxide, the connecting element is provided with a thermal desired breaking point. Said thermal desired breaking point fulfills the function of a fusible link. If a supercritical quantity of electrical charge then flows onto the backup capacitance, it is the case that, as a result of the tripping of the fusible link, although the backup capacitance is permanently disconnected from the rest of the circuit situated on the chip, the semiconductor component is not destroyed.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a cross-section of an n-MOS transistor according to the prior art.

FIG. 2 illustrates an exemplary embodiment of the invention in plan view.

FIG. 3 illustrates an electrical equivalent circuit diagram of the exemplary embodiment of the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

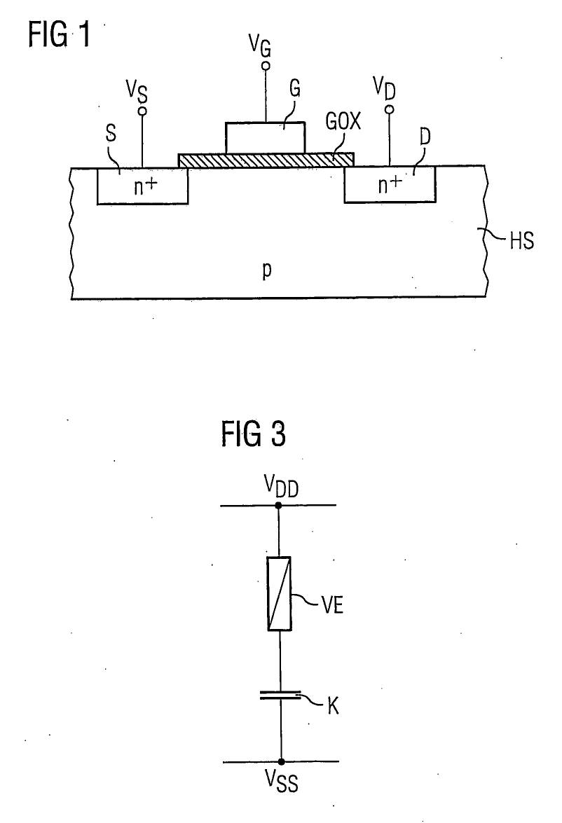

FIG. 1 illustrates an n-MOS transistor. Two n⁺-doped regions are introduced as source S and drain D in a p-doped semiconductor substrate HS. The gate G is situated above a gate oxide GOX. Source S, drain D and gate G are led via respectively associated contacts V_{S}, V_{D} and V_{G} to the surface of a wiring plane of a semiconductor component in order to be available for further wiring. On account of the geometry present, both the arrangement of drain D with respect to gate G and the arrangement of source S with respect to G in each case constitute a capacitance.

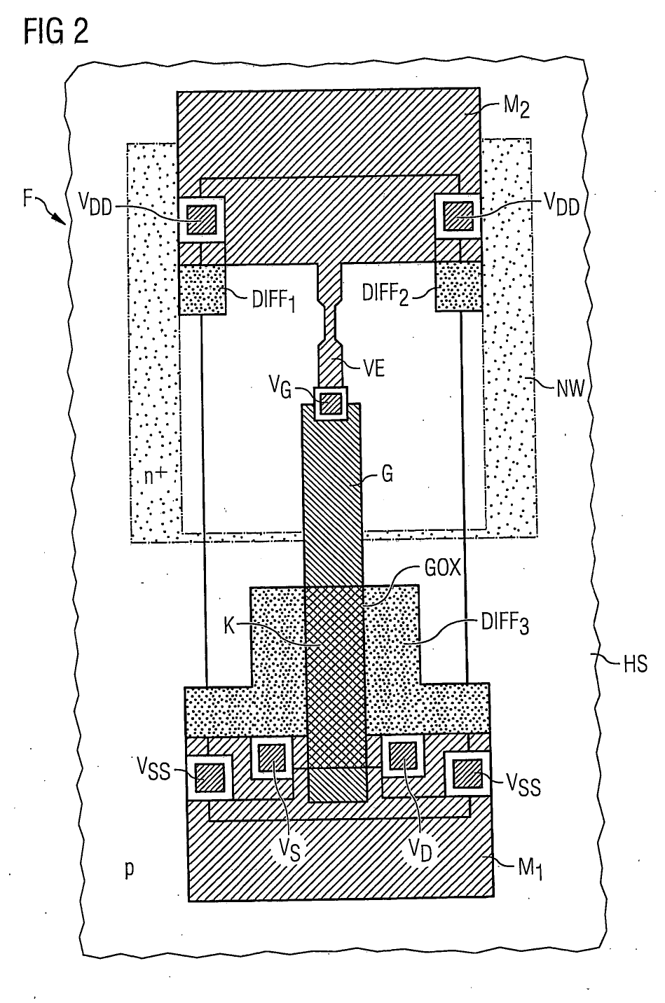

FIG. 2 illustrates an exemplary embodiment of the invention on the basis of the plan view of a filler cell F. A p-doped semiconductor substrate HS has an n⁺-type well NW. Said n⁺-type well NW is not required for the functionality of the backup capacitance described here, but, for reasons of uniformity and the additional pn junction capacitance, a deviation is not made from the standard cell layout. The same applies to diffusion zones DIFF₁ and DIFF₂. Situated outside the n⁺-type well NW is an n-MOS transistor with source S, drain D and gate G that is utilized as a capacitance. The arrangement of the diffusion zone DIFF₃ contributes to maximizing the capacitance value of the capacitance K. A gate contact V_{G} including polysilicon, for example, is led to a connecting element VE. As a result of corresponding geometrical overlapping, an effective capacitance K is realized between gate G and source S and also between gate G and drain D. Furthermore, by means of a metallization M₁, a first supply voltage V_{SS} is led both to the source terminal V_{S} and to the drain terminal V_{D} of the transistor, while a second supply voltage V_{DD} is applied to the connecting element VE by means of a metallization M₂.

FIG. 3 illustrates a simplified equivalent circuit diagram of the exemplary embodiment according to FIG. 2. The connecting element VE acting as a thermal desired breaking point is connected in series with the capacitance K. A first supply voltage V_{SS} is led to the capacitance K and a second supply voltage V_{DD} is applied to the connecting element VE.

On embodiment of the invention provides a semiconductor component with at least one thin oxide transistor, the gate of which is directly connected to a first electrical potential by means of a connecting element. The connecting element contains a thermal desired breaking point. In order to realize an integrated backup capacitance, at least one of the further terminals of the thin oxide transistor (source or drain) is directly connected to a second potential, that is different from the first potential.

In one embodiment of the invention, the connecting element is produced from a metal or a metal alloy. Consideration is given in this case in particular to aluminum, copper, or alloys based on aluminum or copper, e.g., AlSiCu. Use of these metals or metal alloys affords the possibility to have recourse to existing fabrication technologies. Furthermore, metallic fusible links have well-defined tripping ranges, that is to say that the critical current can be defined by the cross-sectional geometry of the thermal desired breaking point within a comparatively small tolerance range.

In another embodiment of the invention, the connecting element is produced from polysilicon. By virtue of this embodiment, the filler cell affords improved wiring possibilities since a larger proportion of the chip area remains free of metal and, consequently, more space is available for routing interconnects.

The fusible link can furthermore be realized in any desired rewiring plane within the semiconductor component. In this case, it is not necessary, for the fusible link to be embodied in the topmost, if appropriate at least partly visible metallization plane. In contrast to electro-optical desired breaking points (laser fuses) which are used for connecting or disconnecting specific circuit elements, it is not necessary here to keep the fusible link openly accessible.

In order to maximize the capacitance value in one embodiment, the thickness of the gate oxide of the thin oxide transistor is chosen to be as small as possible. On account of fundamental physical and fabrication-technical limitations, a layer thickness range of approximately 0.5 to 3 nm proves to be advantageous in one case. This ensures that both the number of individual backup capacitances distributed over the chip and the cumulative capacitance are optimized. In this case, the selection of the thickness of the gate oxide is in particular also oriented to the existing fabrication technology or technology generation.

In another embodiment, the capacitance of the thin oxide transistor can be increased by electrically conductively connecting the source and drain to one another. As a result of this interconnection, source-gate and drain-gate capacitances are added and thus produce a significantly increased capacitance value depending on cell geometry. In this embodiment, the gate is connected to a first supply voltage by means of a connecting element and the source and drain are connected to a second supply voltage. In this case, it is possible, in particular, either to embody the two supply voltages as complementary, symmetrical potentials or to realize one of the two supply voltages as zero potential (ground potential).

In order to minimize the outlay for the design implementation of the backup capacitances, the thin oxide transistor may, with regard to its layout, be part of an existing standard cell library. Through the use of standardized filler cells, it is possible to ensure a fast—and hence inexpensive—implementation in existing design flows. Since filler cells already have to be integrated in many semiconductor components if only for reasons of obtaining a sufficient wiring capability, the gate capacitances present anyway in this case can be utilized as backup capacitances.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor component comprising:
at least one thin oxide transistor, the gate of which is connected to a supply voltage by means of a connecting element;
wherein the thin oxide transistor is embodied as an integrated backup capacitance; and
wherein the connecting element contains a thermal desired breaking point.

2. The semiconductor component of claim 1, wherein the connecting element comprises a metal or a metal alloy.

3. The semiconductor component of claim 2, wherein the metal or the metal alloy comprises one of the group comprising aluminum, copper, and an alloy based on aluminum or copper.

4. The semiconductor component of claim 1, wherein the connecting element comprises polysilicon.

5. The semiconductor component of claim 1, wherein the connecting element is embodied in an inner metallization plane.

6. The semiconductor component of claim 1, wherein the thickness of the gate oxide of the thin oxide transistor lies between 0.5 and 3 nm.

7. The semiconductor component of claim 1, wherein the source and drain of the thin oxide transistor are electrically conductively connected to one another.

8. The semiconductor component of claim 1, wherein the thin oxide transistor is part of a standard cell library.

9. The semiconductor component of claim 8, wherein the standard cell is a filler cell.

10. A semiconductor component comprising:
at least one thin oxide transistor having a source, a drain and a gate, the thin oxide transistor configured as an integrated backup capacitance;
a connecting element configured to connect the gate to a first electrical potential; and
means within the connecting element for providing a thermal desired breaking point.

11. The semiconductor component of claim 10, wherein the means comprises a metal or metal alloy.

12. The semiconductor component of claim 11, wherein the metal or the metal alloy comprises one of the group comprising aluminum, copper, and an alloy based on aluminum or copper.

13. The semiconductor component of claim 10, wherein the connecting element comprises polysilicon.

14. The semiconductor component of claim 10, wherein the connecting element is embodied in an inner metallization plane.

15. The semiconductor component of claim 10, wherein the thickness of the gate oxide of the thin oxide transistor lies between 0.5 and 3 nm.

16. The semiconductor component of claim 10, wherein the source and drain of the thin oxide transistor are electrically conductively connected to one another.

17. The semiconductor component of claim 10, wherein the thin oxide transistor is part of a standard cell library.

18. The semiconductor component of claim 17, wherein the standard cell is a filler cell.

19. A method for forming a semiconductor component comprising:
fabricating a thin oxide transistor with a drain, a source and a gate;
configuring the thin oxide transistor as an integrated backup capacitance;
coupling the gate to a supply voltage via a connecting element; and
forming a thermal desired breaking point within the connecting element.

20. The method of claim 19, further including forming the connecting element from a metal or metal alloy.
